(19) United States
(12) Patent Application Publication
(10) Pub. No.: US 2021/0072301 A1
(43) Pub. Date: Mar. 11, 2021

(54) AUTOMATIC TEST METHOD FOR RELIABILITY AND FUNCTIONALITY OF ELECTRONIC DEVICE

(71) Applicants: Inventec (Pudong) Technology Corp., Shanghai (CN); Inventec Corporation, Taipei (TW)

(72) Inventors: Chin-Lin Hsieh, Taipei (TW); Yu-Ting Weng, Taipei (TW); Che-Cheng Wang, Taipei (TW); Che-Sheng Cheng, Taipei (TW)

(21) Appl. No.: 16/572,573

(22) Filed: Sep. 16, 2019

(30) Foreign Application Priority Data
Sep. 6, 2019 (CN) 201910839859.4

(51) Int. Cl. G01R 31/04; B25J 19/00; G01R 31/327

(52) U.S. Cl. CPC G01R 31/043; G01R 31/3277; B25J 19/0095

(57) ABSTRACT

An automatic test method for reliability and functionality of electronic device is provided to deploy a robotic arm to perform reliability test on a tested component. In the meantime, the test host can directly access the generic log files generated by the tested electronic device without the need of using a third-party test utility on the tested electronic device. Analysis is carried out by the test host using the log files to determine whether each test round generates functional result to the tested component so that data of the functionality can be collected.

### BACKGROUND OF THE INVENTION

### 1. Field of the Invention

The invention relates to an automatic test method, and more particularly, to automatic test method for reliability and functionality of electronic device.

### 2. Description of the Prior Art

Modern electronic devices such as servers, laptop computers, desktop computers, mobile phones, undergo automatic reliability test after the devices are assembled. Conventional robotic arm or robotic arm clamping related test connector is common for such reliability or durability test. The air-driven robotic arm moves backwards/forwards or upwards/downwards during the test to push or press the button, switch, or carry the test connector to repeatedly plug and unplug to an I/O connection port of the electronic device.

However, test mechanism the present day only relates to reliability or durability test. Functionality test should be separately carried out to check its functionality after multiple times of physical plugging/unplugging, button pressing, or switching. Although the operation of reliability test can be carried out by automatic machine, such physical test device has no coverage on functionality test like correct data transmission, power supplying normally. Manual operation to test or examine the functionality should be carried out to see if the electronic component or the connection port function well.

### SUMMARY OF THE INVENTION

The invention provides an automatic test method for reliability and functionality of electronic device to solve the above-mentioned problem.

According to an embodiment of the invention, an automatic test method for reliability and functionality of electronic device includes following steps: establishing connection between a test host and an electronic device to be tested; the test host obtaining a first log file generated by the electronic device; the test host controlling a test fixture to perform a testing action on a tested component of the electronic device; during the testing action, the test host obtaining a second log file generated by the electronic device and comparing the second log file with the first log file; and determining whether the functionality of the testing action is normal according to a comparison result of the first log file and the second log file. Performing the testing action on the tested component and deactivating the testing action relate to a reliability test on the tested component. Determining whether the functionality of the testing action is normal according to the comparison result of the first log file and the second log file relates to a functionality test on the tested component.

According to the embodiment of the invention, the method further includes step: initialization of the test fixture by the test host.

According to the embodiment of the invention, the method further includes step: the test host setting up parameters related to the electronic device according to the electronic device.

According to the embodiment of the invention, the first log file and the second log file are generic log files generated by the electronic device.

According to the embodiment of the invention, the test host obtaining the first log file includes steps: the test host sending a flag to the electronic device and the electronic device executing a command according to the flag to generate the first log file and returning the first log files to the test host. The flag includes command for retrieving information of the tested component.

According to the embodiment of the invention, the test host obtaining the second log file includes steps: the test host sending a flag to the electronic device and the electronic device executing a command according to the flag to generate the second log file and returning the second log files to the test host. The flag includes command for retrieving information of the tested component during the testing action.

According to the embodiment of the invention, the reliability test on the tested component includes a plurality of testing actions and a plurality of deactivating the testing actions and the functionality test on the tested component includes recording a result of functional abnormalities of the plurality of testing actions and the plurality of deactivating the testing actions.

According to the embodiment of the invention, establishing connection between the test host and the electronic device comprises at least one of the following: establishing a shared network storage accessible for the test host and the electronic device, direct wired connecting the test host and the electronic device, and wirelessly connecting the test host and the electronic device.

According to the embodiment of the invention, the test fixture is a robotic arm, the tested component is a key button or a switch, and the testing action is pressing or switching the tested component using the test fixture.

According to the embodiment of the invention, the test fixture is a robotic arm and a test connector, the tested component is a connection port of the electronic device, and the testing action is plugging the test connector to the tested component.

The automatic test method for reliability and functionality of electronic device such as servers, laptop computers, desktop computers, or mobile phones provided by the embodiments of the invention deploys a robotic arm to perform reliability test on a tested component like the connection port, I/O interfaces, or switches. In the meantime, the test host can directly access the generic log files generated by the tested electronic device without the need of using a third-party test utility on the tested electronic device. Analysis is carried out by the test host using the log files to determine whether each test round generates functional result to the tested component so that data of the functionality can be collected. Massive manual operations can be replaced by such automatic procedures, saving tremendous amount of time and cost spent on manual operations. Furthermore, a complete record of function abnormality can be provided with the reliability test for follow-up analysis and improvement references.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is an illustration showing flow chart of an automatic test method for reliability and functionality of electronic device according to an embodiment of the invention.

FIG. 2 to FIG. 5 are illustrations showing embodiments of various types of connections among the test host, the electronic device, and the test fixture.

### DETAILED DESCRIPTION

Certain terms are used throughout the following description and claims to refer to particular system components. As one skilled in the art will appreciate, manufacturers may refer to a component by different names. In the following discussion and in the claims, the terms “include” and “comprise” are used in an open-ended fashion. Also, the term “couple” is intended to mean either an indirect or direct electrical/mechanical connection. Thus, if a first device is coupled to a second device, that connection may be through a direct electrical/mechanical connection, or through an indirect electrical/mechanical connection via other devices and connections.

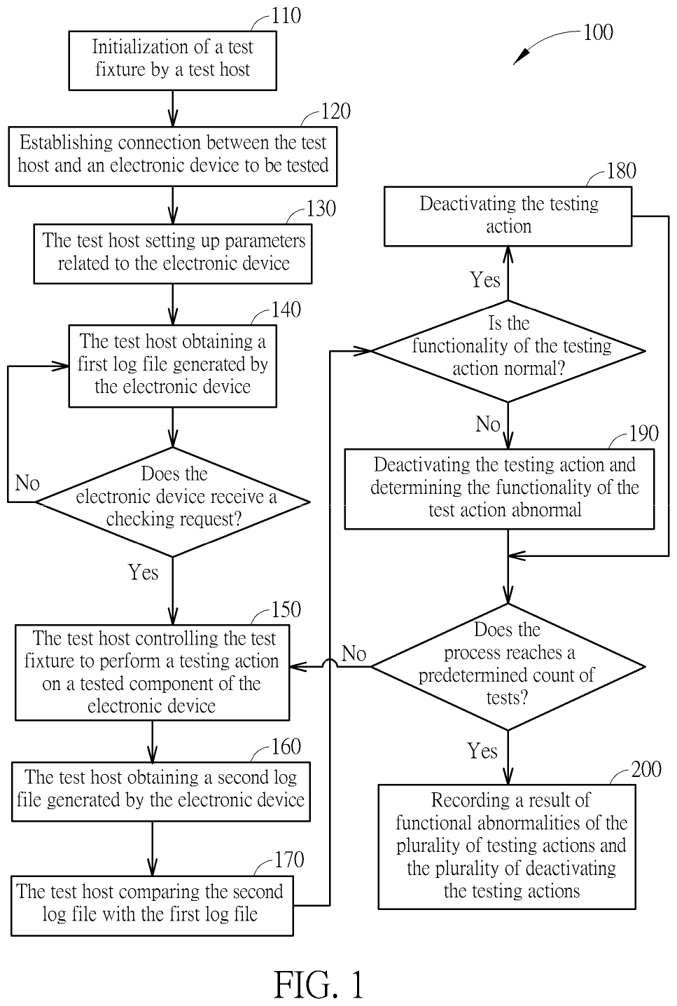

Please refer to FIG. 1, which is an illustration showing flow chart of an automatic test method for reliability and functionality of electronic device according to an embodiment of the invention. The automatic test method 100 for reliability and functionality of electronic device includes following steps:

Step 110: initialization of a test fixture by a test host;

Step 120: establishing connection between the test host and an electronic device to be tested;

Step 130: the test host setting up parameters related to the electronic device;

Step 140: the test host obtaining a first log file generated by the electronic device;

Step 150: the test host controlling the test fixture to perform a testing action on a tested component of the electronic device;

Step 160: the test host obtaining a second log file generated by the electronic device;

Step 170: the test host comparing the second log file with the first log file and determining whether the functionality of the testing action is normal according to a comparison result of the first log file and the second log file;

Step 180: deactivating the testing action;

Step 190: deactivating the testing action and determining the functionality of the test action abnormal;

Step 200: recording a result of functional abnormalities of the plurality of testing actions and the plurality of deactivating the testing actions.

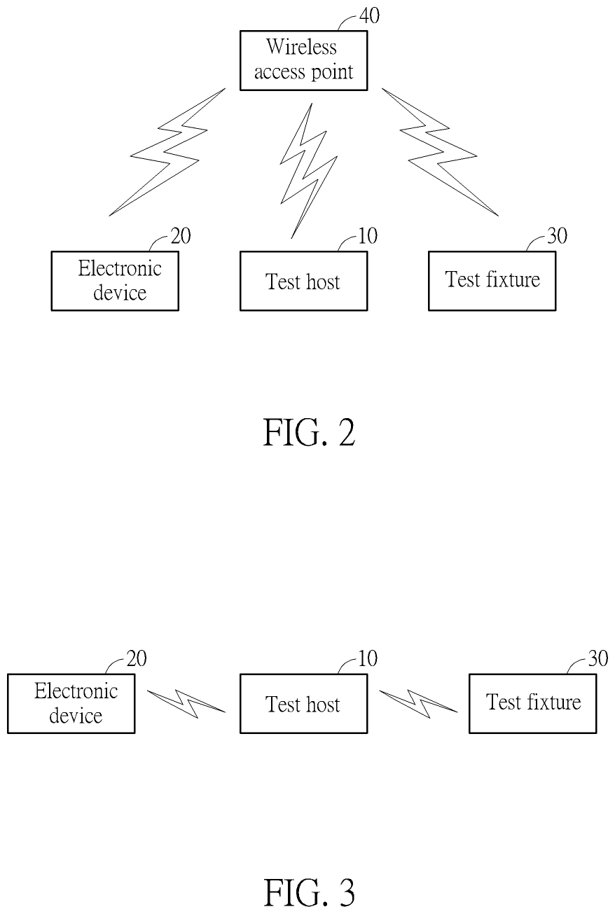

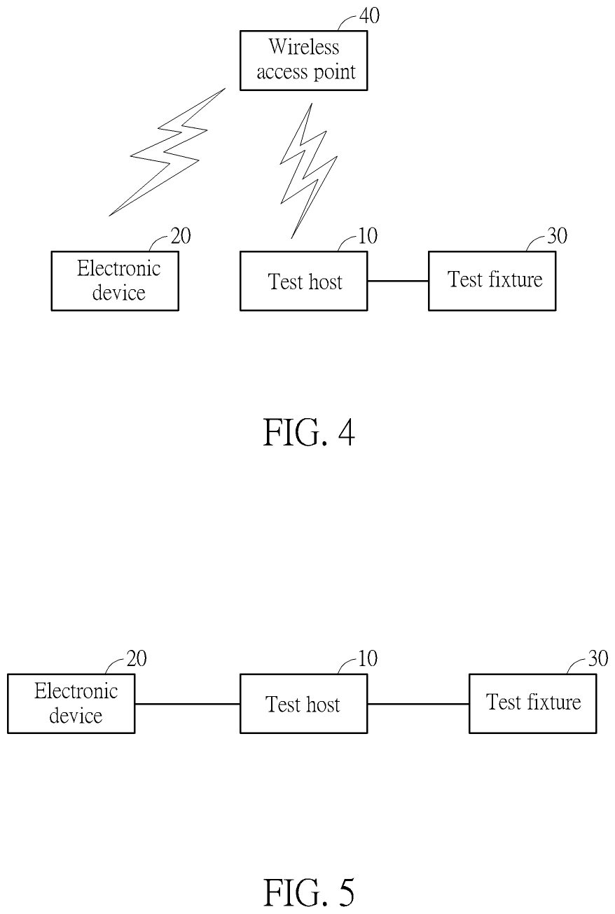

Please refer to FIG. 2 to FIG. 5. FIG. 2 to FIG. 5 are illustrations showing embodiments of various types of connections among the test host, the electronic device, and the test fixture. Connections among the test host 10, the electronic device 20, and the test fixture 30 can be either wired or wireless. For example, FIG. 2 illustrates connections among the test host 10, the electronic device 20, and the test fixture 30 via a wireless access point 40 (AP), which is further connected to a shared network storage or has a built-in shared network storage accessible for the test host 10 and the electronic device 20 as data storage. For the embodiment in FIG. 3, the test host 10 directly connects the electronic device 20 and the test fixture 30 respectively using wireless communication, WIFI interface for example. For the embodiment in FIG. 4, connection between the test host 10 and the electronic device 20 is established via the wireless access point 40 whereas the connection between the test host 10 and the test fixture 30 uses physical USB interface or other practical physical transmission interfaces. For the embodiment in FIG. 5, the test host 10 and the electronic device 20 can also be connected to each other using direct wired connection such as physical NIC cable.

According to the method in FIG. 1, Step 110 of the method 100 of the invention provides that the test host 10 carries out initialization of the test fixture 30. The test host 10 and the test fixture 30 (a robotic arm or a robotic arm clamping a test connector) are connected with wire or wirelessly where initialization of the test fixture 30 can be power on operation, setting parameters of the test fixture 30, setting test type or test stroke, in which way enables the test fixture 30 to perform every testing action required by the test host 10 like plugging/unplugging the test connector, pressing the button, or switching the switch. Then in Step 120, connection between the test host 10 and the electronic device 20 to be tested is established. As described earlier, data can be transferred between the test host 10 and the electronic device 20 once connection is established between the test host 10 and the electronic device 20, with physical wired cable or wireless network interface. Step 130 comes after the connection establishment of Step 120 that the test host 10 sets up parameters related to the electronic device 20 based on the electronic device 20 and each component of the electronic device 20 to be tested. The parameters contain at least one or more of the following: the type of the tested component, physical size, and module. It should be noted that Step 110 deals with initialization of the test fixture 30 whereas Step 130 can be regarded as carrying out relevant initialization and parameter setup of a component of the electronic device 20 to be tested, so that the test host 10 is able to access and analyze pertinent log files in the following steps.

After the environment setup in previous steps, the test host 10 is ready to perform the reliability test and functionality test on the tested component. In Step 140, the test host 10 manages to access/obtain the log files of the electronic device 20 by sending a request command, which will be responded by the OS of the electronic device 20 returning a log file generated using internal commands. In one embodiment, the test host 10 sends a flag including commands for retrieving information of the tested component to the electronic device 20, which returns a confirmation signal in response to the flag and according to the flag, executes a command to generate and return a first log file by its own operating system (OS). The confirmation signal and the first log file are obtained and read by the test host 10 via the connection established in Step 120. It should be noted that the test host 10 will continue to send the flag to the electronic device 20 if it fails to receive the returned confirmation signal (Step 140 is repeated). The first log file generated by the electronic device 20 preferably includes at least status data related to the tested component like the status of inactivated/turned-off/unconnected connector or some specific status of the component, i.e., the status of the component before the testing action of Step 150.

Then in Step 150, the test host 10 controls the test fixture 30 to perform a testing action on the tested component of the electronic device 20. In one embodiment, the test fixture 30 can be a robotic arm, 3D printed or mechanically manufactured, with a test head whereas the tested component can be a key button, a power button, a switch, or a volume control key, and the testing action is correspondingly to press or switch the tested component using the robotic arm, which is automatically performed by the test host 10 controlling the test fixture 30 with software. In another embodiment, as the tested component is a connection port of the electronic device 20, the test fixture 30 can be a robotic arm further clamping a test connector corresponding to the connection port, and the testing action is the robotic arm bringing the test connector to plug into the tested component.

During the testing action of the above Step 150, Step 160 provides that the test host 10 again obtains the log files of the electronic device 20 by sending a request command, which will be responded by the OS of the electronic device 20 returning a log file generated using internal commands. The test host 10 sends a flag including commands for retrieving information of the tested component to the electronic device 20, which returns a confirmation signal in response to the flag and according to the flag, executes a command to generate and return a second log file by its own operating system (OS). The confirmation signal and the second log file are obtained and read by the test host 10 via the connection established in Step 120. For a normally functioning tested component, the status of the component presents changes that properly respond to the testing action, and hence the second log file generated by the electronic device 20 preferably includes at least status data related to the tested component like the status of activated/turned-on/connected connector or another specific status of the component.

It should be noted that no additional third-party test utility is needed to be installed on the tested electronic device 20 in the method of the invention. In such case, as the test host 10 controls the test fixture 30 to perform the testing action on the electronic device 20, the first log file and the second log file obtained are logs native to and generated by the operation system's own command of the electronic device 20. In other words, the first log file and the second log file are generic log files generated by the electronic device 20. In Step 170, the test host 10 compares the generic second log file with the generic first log file, specifically content of the log files that relates to the status of the tested component, and determines accordingly whether the functionality of the tested component is normal when performing the testing action. Step 180 follows, if the functionality is normal, to deactivate the testing action, i.e., cancelling pressing the button, switching the switch back to an original position, or unplugging the test connector from the connection port. If the functionality is determined to be abnormal, executing Step 190 to deactivate the testing action and also record/tag this testing action functionally abnormal.

In the method provided by the invention, performing the testing action in Step 150 and deactivating the testing action in the following Step 180 and Step 190 relate to the physical reliability test on the tested component and determining whether the functionality of the testing action is normal according to the comparison result of the first log file and the second log file obtained in each testing action relates to the functionality test on the tested component. Steps 150˜180 (or 190) will be repeated for a predetermined testing count to perform a plurality of testing actions and a plurality of deactivating the testing actions on the tested component, however the testing action is deactivated in functionally normal way (Step 180) or in functionally abnormal way (Step 190). In other words, the reliability test of the invention represents a series of physical tests while the functionality test on the tested component includes recording a result of functional abnormalities of each of the plurality of physical tests. After going through the predetermined test count, recording and generating a report of a result of the plurality of testing actions that have functional abnormalities in Step 200 for following backup or relevant analysis.

The automatic test method for reliability and functionality of electronic device such as servers, laptop computers, desktop computers, or mobile phones provided by the embodiments of the invention deploys a robotic arm to perform reliability test on a tested component like the connection port, I/O interfaces, or switches. In the meantime, the test host can directly access the generic log files generated by the tested electronic device without the need of using a third-party test utility on the tested electronic device, and therefore the performance and outcome of the tested electronic device is closest to the actual using experience of an end user. Analysis is carried out by the test host using the log files to determine whether each test round generates functional result to the tested component so that data of the functionality can be collected.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An automatic test method for reliability and functionality of electronic device, comprising steps:
establishing connection between a test host and an electronic device to be tested;
the test host obtaining a first log file generated by the electronic device;
the test host controlling a test fixture to perform a testing action on a tested component of the electronic device;
during the testing action, the test host obtaining a second log file generated by the electronic device and comparing the second log file with the first log file; and
determining whether the functionality of the testing action is normal according to a comparison result of the first log file and the second log file;
wherein performing the testing action on the tested component and deactivating the testing action relate to a reliability test on the tested component and determining whether the functionality of the testing action is normal according to the comparison result of the first log file and the second log file relates to a functionality test on the tested component.

2. The method of claim 1, further comprising: initialization of the test fixture by the test host.

3. The method of claim 1, further comprising: the test host setting up parameters related to the electronic device according to the electronic device.

4. The method of claim 1, wherein the first log file and the second log file are generic log files generated by the electronic device.

5. The method of claim 1, wherein the test host obtaining the first log file comprises steps:
the test host sending a flag to the electronic device; and
the electronic device executing a command according to the flag to generate the first log file and returning the first log files to the test host;
wherein the flag includes command for retrieving information of the tested component.

6. The method of claim 1, wherein the test host obtaining the second log file comprises steps:
the test host sending a flag to the electronic device; and
the electronic device executing a command according to the flag to generate the second log file and returning the second log files to the test host;
wherein the flag includes command for retrieving information of the tested component during the testing action.

7. The method of claim 1, wherein the reliability test on the tested component includes a plurality of testing actions and a plurality of deactivating the testing actions and the functionality test on the tested component includes recording a result of functional abnormalities of the plurality of testing actions and the plurality of deactivating the testing actions.

8. The method of claim 1, wherein establishing connection between the test host and the electronic device comprises at least one of the following: establishing a shared network storage accessible for the test host and the electronic device, direct wired connecting the test host and the electronic device, and wirelessly connecting the test host and the electronic device.

9. The method of claim 1, wherein the test fixture is a robotic arm, the tested component is a key button or a switch, and the testing action is pressing or switching the tested component using the test fixture.

10. The method of claim 1, wherein the test fixture is a robotic arm and a test connector, the tested component is a connection port of the electronic device, and the testing action is plugging the test connector to the tested component.
